(19) United States
(12) Patent Application Publication
(10) Pub. No.: US 2025/0108439 A1
(43) Pub. Date: Apr. 3, 2025

(54) HARD FILM-COATED CUTTING TOOL

(71) Applicant: KORLOY INC., Seoul (KR)

(72) Inventors: Yeong Ju JO, Cheongju-si, Chungcheongbuk-do (KR); Kyoung Il KIM, Cheongju-si, Chungcheongbuk-do (KR); Jin Han GWON, Cheongju-si, Chungcheongbuk-do (KR); Hyung Jin KIM, Cheongju-si, Chungcheongbuk-do (KR); Seong Yeon AHN, Cheongju-si, Chungcheongbuk-do (KR); Seung Su AHN, Cheongju-si, Chungcheongbuk-do (KR); Je Hun PARK, Cheongju-si, Chungcheongbuk-do (KR)

(21) Appl. No.: 18/729,199

(22) PCT Filed: Dec. 15, 2022
(86) PCT No.: PCT/KR2022/020473

§ 371 Date: Jul. 16, 2024

(30) Foreign Application Priority Data
Mar. 14, 2022 (KR) 10-2022-0031334

(51) Int. Cl. B23B 27/14

(52) U.S. Cl. CPC B23B 27/148; B23B 2224/00; B23B 2228/08; B23B 2228/105

(57) ABSTRACT

A hard film-coated cutting tool comprises: a hard base material and a hard film formed on the hard base material, wherein: assuming that a colorimetric diffusion reflectance value is L_{SCER} and a total reflectance value is L_{SCIR}, the relationship of 0.65≤L_{SCER}/L_{SCIR}≤0.85 is satisfied, and when surface roughness is measured on the rake surface of the hard film within the range of 100 μm from the edge, an arithmetic average height S_{aR} is within the range of 0.2 μm≤S_{aR}≤0.5 μm; and assuming that, at a flank surface of the hard film, a colorimetric diffusion reflectance value is L_{SCEF} and a total reflectance value is L_{SCIF}, the relationship of L_{SCEF}/L_{SCIF}≥0.9 is satisfied, and when surface roughness is measured on the flank surface of the hard film within the range of 100 μm from the edge, an arithmetic average height S_{aF} is within the range of 0.15 μm≤S_{aF}≤0.4 μm.

### TECHNICAL FIELD

The present invention relates to a hard film-coated cutting tool including a hard base material such as cemented carbide, cermet, ceramic, or cubic boron nitride used in cutting tools and a hard film formed on the hard film, and more particularly, a hard film-coated cutting tool on which surface roughness of each of a rake surface and a flank surface varies to suit characteristics of each surface.

### BACKGROUND ART

In tools for machining high-hardness workpieces with a hardness of 50 or more according to the HRC standard, such as high-hardness steel, technologies for applying a hard film made of various ceramics on a hard base material such as cemented carbide, cermet, end mills, and drills are being adopted to improve cutting performance and lifespan.

The hard film formed through deposition technologies on the hard base material has a risk of peeling by increasing stress of the hard film due to a difference in lattice constant between the hard base material and the hard film and characteristics of a physical vapor deposition method. To solve this problem, adhesion of the hard film to the base material has been improved through pre-treatment, etching, an adhesion layer, a thin film having a multi-layered structure, and a post-processing technology.

When applying processes such as the pre-treatment and the etching, a specific surface area of a surface of the hard base material may increase to improve the adhesion between the base material and the thin film. However, depending on the workpiece, especially in stainless steel and inconel cutting, the increasing of the specific surface area may lead to increase in weldability between the thin film and the workpiece, thereby deteriorating the lifespan of the tool due to tearing of the hard film.

To solve this problem, in the related art, a post-treatment process of the hard film has been applied to reduce surface roughness of the tool, thereby improving lubricity. However, in spite of these efforts, there are limits to improve the roughness through the post-treatment process of the hard film, and there are disadvantages in terms of manufacturing efficiency due to an additional process. In addition, even in machining situations in the hard base material state after the hard film is peeled, the problem of the reduction in lifespan of the tool occurs by the increasing weldability due to the still high specific surface area of the hard base material, and thus, it is necessary to solve the problem. However, if the specific surface area of the hard base material is excessively reduced, the adhesion between the hard base material and the hard film may decrease to accelerate the peeling of the film.

### DISCLOSURE OF THE INVENTION

### Technical Problem

An object of the present invention is to provide a hard film-coated cutting tool having excellent welding resistance and wear resistance.

### Technical Solution

To achieve the objective as above, a hard film-coated cutting tool according to the present invention includes: a hard base material; and a hard film formed on the hard base material, wherein, if assumed that a colorimetric diffusion reflectance value is L_{SCER}, and a total reflectance value is L_{SCIR} on a rake surface of the had film, a relationship of 0.65≤L_{SCER}/L_{SCIR}≤0.85 is satisfied, and when surface roughness is measured on the rake surface of the hard film within a range of 100 μm from an edge, an arithmetic average height S_{aR} is within a range of 0.2 μm≤S_{aR}≤0.5 μm, and if assumed that the colorimetric diffusion reflectance value is L_{SCEF}, and the total reflectance value is L_{SCIF} on a flank surface of the hard film, a relationship of L_{SCEF}/L_{SCIF}≥0.9 is satisfied, and when surface roughness is measured on the flank surface of the hard film within a range of 100 μm from the edge, an arithmetic average height S_{aF} is within a range of 0.15 μm≤S_{aF}≤0.4 μm.

In addition, maximum height roughness R_{yR} of the hard base material within a range of 300 μm from the edge on the rake surface of the hard base material in a cross-section of the cutting tool may be 1 μm≤R_{yR}≤2 μm, and maximum height roughness R_{yF} of the hard base material within a range of 300 μm from the edge on the flank surface of the hard base material in the cross-section of the cutting tool may be 2 μm≤R_{yF}≤5 μm.

In addition, the hard film may have a composition that satisfies Formula 1 below and include one or more films, each of which has a thickness in a range of 0.1 μm to 10.

[Formula 1]Al_{(1-a-b-c)}TiₐCr_{b}Me_{c}N (where Me is any one or more of B, Si, Zr, V, Mn, Nb, Mo, Ta, W, 0≤a≤0.6, 0≤b≤0.5, 0≤c≤0.15, and has to comprise at least one of Ti and Cr)

In addition, the number of droplets, each of which has a diameter of 3 μm or more within 100 μm from the edge on the rake surface of the hard film, may be 5% or less of the total number of droplets.

### Advantageous Effects

According to the present invention, it may be possible to provide the cutting tool with the excellent adhesion of the hard film to the base material and the excellent welding resistance to the workpiece. In addition, the process efficiency may be improved in the manufacture of the cutting tool having the hard film.

### BRIEF DESCRIPTION OF THE DRAWINGS

FIG. 1 is a schematic view for explaining a cutting tool on which a hard film is disposed on a hard base material according to an embodiment of the present invention.

FIG. 2 is a scanning electron microscope image illustrating a surface of the hard film according to an embodiment of the present invention.

### MODE FOR CARRYING OUT THE INVENTION

Hereinafter, detailed descriptions related to well-known functions or configurations will be ruled out in order not to unnecessarily obscure subject matters of the present invention. Furthermore, when it is described that one includes some elements, it should be understood that it may comprise only those elements, or it may include other elements as well as those elements if there is no specific limitation.

A hard film-coated cutting tool according to the present invention may include a hard base material, and a hard film formed on the hard base material, wherein, if assumed that a colorimetric diffusion reflectance value is L_{SCER}, and a total reflectance value is L_{SCIR} on a rake surface of the had film, a relationship of 0.65≤L_{SCER}/L_{SCIR}≤0.85 is satisfied, and when surface roughness is measured on the rake surface of the hard film within a range of 100 μm from an edge, an arithmetic average height S_{aR} is within a range of 0.2 μm≤S_{aR}≤0.5 μm, and if assumed that the colorimetric diffusion reflectance value is L_{SCEF}, and the total reflectance value is L_{SCIF} on a flank surface of the hard film, a relationship of L_{SCEF}/L_{SCIF}≥0.9 is satisfied, and when surface roughness is measured on the flank surface of the hard film within a range of 100 μm from the edge, an arithmetic average height S_{aF} is within a range of 0.15 μm≤SₐF≤0.4 μm.

One of methods for measuring surface roughness is to use a colorimeter. The colorimeter measures reflected light. Light that is incident onto a surface of an object and reflected at the same angle is called specular reflectance, and light that is not specularly reflected, but is scattered and reflected in various directions is called diffuse reflectance. The combination of the specular reflectance and diffuse reflectance is called total reflectance.

An amount of specular reflectance is greater than the diffuse reflectance on a glossy surface, and an amount of diffuse reflectance is relatively large on a rough surface. Thus, the higher a fraction of the diffuse reflectance value in the total reflectance value, the rougher the surface.

In the cutting tool, a flank surface and a rake surface may experience different environments during the machining process. Particularly, the rake surface may be a surface through which a machining chip generated from a workpiece pass during the machining process passes and on which the hard film is easily peeled by fusion between the machining chip and the surface of the cutting tool.

Thus, since the flank surface and the rake surface need to have different characteristics to suit the different environments, in the present invention, surface roughness of the flank surface and surface roughness of the rake surface were set to be different from each other.

For this, in the present invention, the roughness of the flank surface increases to increase in rate of the diffuse reflectance and increase in adhesion between the hard film and the hard base material. On the other hand, a rate of the diffuse reflectance value on the rake surface was lower than that on the flank surface and was maintained within a certain range to control the surface roughness, thereby improving welding resistance of the hard film.

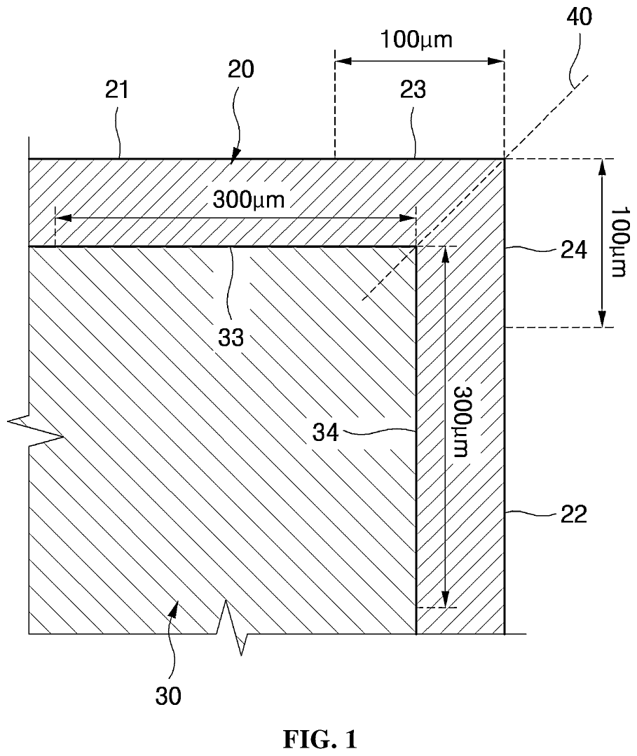

In more detail with reference to FIG. 1, roughness of a flank surface 22 of a hard film 20 increases by ensuring a diffuse reflectance value to a value more than 90% of the total reflectance value, and simultaneously, an arithmetic mean height S_{aR} that is appeared when measuring the roughness was set to be in a range of 0.2 μm≤S_{aR}≤0.5 μm. Since the diffuse reflectance value is obtained by measuring an amount of light scattered from the surface, it is difficult to determine how much difference in surface height occurs due to the roughness. Thus, it may be difficult to control a large height difference that is appeared on the surface of the hard film 20, and thus, since wear resistance of the hard coating 20 is reduced, it is necessary to control the arithmetic mean height to a certain level when measuring the surface roughness. For this, the arithmetic mean height S_{aR} on the flank surface is preferably in a range of 0.2 μm to 0.5 μm, and if it is less than 0.2 μm, adhesion to the hard base material 30 may be problematic, and if it exceeds 0.5 μm, chipping resistance of the flank surface 22 may be deteriorated. Particularly, as illustrated in FIG. 1, that the arithmetic mean height is controlled in the range 24 within 100 μm from an edge is because this area is an area that is likely to be in contact with the workpiece in actual machining and particularly requires control of fine characteristics.

In addition, as described above, it is advantageous for the rake surface 21 to be less rough than the flank surface 22 for the welding resistance. For this, in the present invention, a ratio of the diffuse reflectance value to the total reflectance value according to the colorimeter on the rake surface 21 is controlled to be in a range of 0.65 to 0.85. If the roughness decreases too much, and the diffuse reflectance value becomes too low, the adhesion between the hard base material and the hard film decreases. Conversely, if the roughness increases, and the diffuse reflectance value becomes too high, the welding resistance decreases. In addition, like the flank surface 22, it is necessary to control the arithmetic mean height in the rake surface 21 within a range 23 μm of 100 μm from the edge. That is, the arithmetic mean height S_{aF} was maintained in a range of 0.15 μm to 0.4 μm to ensure that the adhesion to the hard base material 30, the fusion resistance, and the wear resistance are harmonized.

In the hard film-coated cutting tool according to the present invention, maximum height roughness R_{yR} of the hard base material within a range of 300 μm from the edge on the rake surface of the hard base material in a cross-section of the cutting tool may be 1 μm≤R_{yR}≤2 μm, and maximum height roughness R_{yF} of the hard base material within a range of 300 μm from the edge on the flank surface of the hard base material in the cross-section of the cutting tool may be 2 μm≤R_{yF}≤5 μm.

As described above, it is necessary to control the surface roughness of the cutting tool having the hard film to a certain level for the welding resistance. For this, a common method is to control the surface of the cutting tool having the hard film by polishing the surface. However, in this case, there is a problem of reducing a thickness of the hard film, and thus, it difficult to polish the surface beyond a certain level.

On the other hand, when limiting the roughness of the hard base material, although the roughness of the surface of the final cutting tool increases, there is a problem of poor adhesion between the hard base material and the hard film.

In order to solve this problem, in the present invention, the surface roughness on each of the rake surface and flank surface in the hard base material were limited to decrease in roughness on the rake surface on which welding resistance is important and which is required to reduce the surface roughness and increase in surface roughness on the frank surface, on which chipping properties are relatively less important, so as to improve the adhesion between the hard base material and the hard film.

Explaining this again with reference to FIG. 1, in the cutting tool according to the present invention, the maximum height roughness R_{yR} in a range 33 μm within 300 μm from the edge on the rake surface of the hard base material 30 was set to be in a range of 1 μm to 2 μm. On the other hand, the maximum height roughness R_{yF} within 300 μm from the edge on the flank surface 34 was set to be in a range of 2 μm to 5 μm.

On the rake surface, the maximum height roughness R_{yR} needs to be below a certain level to improve the welding resistance to the workpiece. For this, the roughness of the hard base material was controlled so that the maximum height is 2 μm or less, and the roughness is 1 μm or more for the adhesion to the hard film.

Since it is advantageous to have higher roughness on the flank surface than on the rake surface, it is necessary to control the maximum height roughness R_{yF} to be in the range of 2 μm to 5 μm so as to be greater than that on the rake surface.

The roughness of the hard base material may be controlled to a certain level in this manner, and thus, there is no need to perform an additional polishing process on the cutting tool after the final hard film is formed.

The reason in which the measurement of the roughness of the hard base material is limited to a range within 300 μm from the edge is because it is possible to confirm a boundary between the hard base material and the hard film within this range.

In addition, in the hard film-coated cutting tool according to the present invention, the hard film may have a composition that satisfies Formula 1 below and include one or more films, each of which has a thickness in a range of 0.1 μm to 10 μm.

[Formula 1]Al_{(1-a-b-c)}TiₐCr_{b}Me_{c}N (where Me is any one or more of B, Si, Zr, V, Mn, Nb, Mo, Ta, W, 0≤a≤0.6, 0≤b≤0.5, 0≤c≤0.15, and has to comprise at least one of Ti and Cr)

A method of depositing a thin film such as TiN, TiAlN, AlTiN, or Al₂O₃ that is a hard film as the hard film formed on the surface of the cutting tool is used. Among them, the AlTiN thin film was able to improve high-temperature oxidation resistance and wear resistance by forming an Al₂O₃ layer on the surface. However, there was still a need to improve bonding strength, toughness, and lubricity. To improve this, the present invention optimized the composition of the hard film to satisfy various requirements by combining Cr and other metal elements.

When a composition of Al is larger than that of each of Ti and Cr, wear resistance, oxidation resistance and lubricity are superior, but when an Al content is too high, there is a problem of increasing in chipping property, and thus, it is preferable that contents of Ti and Cr are 0≤a≤0.6, 0≤b≤0.5.

Me that is added as other elements may improve the chipping resistance, the heat resistance, and the wear resistance of the hard film, but when the content is high, since it acts as a cause of increasing residual stress due to an increase in an amorphous phase, it is preferable that the content c of Me, which is other elements is in a range of 0 to 0.15.

In the hard film-coated cutting tool according to the present invention, the number of droplets, each of which has a diameter of 3 μm or more within 100 μm from the edge on the rake surface of the hard film, may be 5% or less of the total number of droplets.

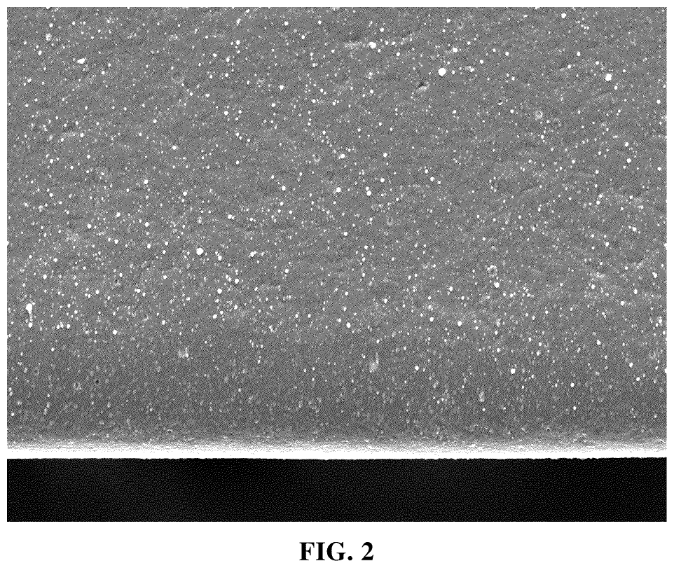

The hard film formed through the deposition may be formed in a droplet shape depending on the roughness of the hard base material (see FIG. 2). A size of each of the droplets may affect physical properties of the hard film. If the number of droplets is too large, a frequency of the chipping and peeling of the hard film may increase to cause rapid end of the lifespan during interrupted machining, and thus, it is preferable that the number of droplets, each of which has a diameter of 3 μm or more, is 5% or less of the total number of droplets.

### Embodiment

A polishing process was applied to a hard base material made of cemented carbide through a microblast honing process or a diamond brush honing process, and then, the hard film was formed using arc ion plating that is a physical vapor deposition (PVD) method.

In the process of polishing the hard base material, paste containing diamond particles, each of which has a size of 1 μm to 5 μm, was used, and arc targets of TiAl, AlCr, TiAlSi, and AlCrSi were used as targets for applying the hard film.

After performing wet microblasting the hard base material and then washing the hard base material using ultra-pure water, the hard base material was dried and mounted along a circumference at a predetermined radial distance from a central axis of a rotary table in a coating furnace, and an initial vacuum pressure in the coating furnace was set to 8.5×10⁻⁵ Torr or less.

After heating to a temperature of 400° C. to 600° C., a bias voltage of −400 V to −200 V was applied to the rotating base material on the rotary table under an Ar gas atmosphere to perform Ar ion bombardment for 30 minutes to 90 minutes. A gas pressure for coating was maintained at 50 mTorr or less, preferably 40 mTorr or less to form a film.

The film was formed using TiAl, AlCr, TiAlSi, and AlCrSi targets under conditions such as a bias voltage of −100 V to −30 V, arc current of 100 A to 150 A, and a pressure of 20 mtorr to 40 mtorr by injecting N₂ as a reaction gas, and the coating conditions may vary depending on equipment characteristics and conditions.

The films were manufactured under the above-described conditions according to Comparative Examples and Embodiment of the present invention, and a hard film having a thickness of 1.5 μm to 2.0 μm was formed using target TiAl (composition ratio 50:50) and TiAlSi (composition ratio 30:60:10) as in Comparative Examples 1 to 3 and Embodiment 1, and a hard film having a thickness of 3.5 μm to 4.0 μm was formed using target TiAl (composition ratio 50:50), AlCr (composition ratio 70:30), and AlCrSi (composition ratio 60:30:10) as in Comparative Examples 4 to 6 and Embodiment 2. Information on a colorimeter value, a roughness value, and a maximum height roughness value of the hard base material in a cross-section on the corresponding surface is shown in Table 1 below.

TABLE 1

| | | | | | | | Maximum height | |
|---|---|---|---|---|---|---|---|---|
| | | | | | | | roughness in | |
| | | | | | Surface roughness | | cross-section | |
| | Surface colorimetric value | | | | Rake | Flank | Rake | Flank |
| | Rake surface | | Flank surface | | surface | surface | surface | surface |
| | | L_{SCE}/L_{SCI} | | L_{SCE}/L_{SCI} | S_{aR} | S_{aF} | R_{yR} | R_{yF} |
| Classification | L_{SCE} | (%) | L_{SCE} | (%) | (μm) | (μm) | (μm) | (μm) |
| Comparative | 45.1 | 93 | 48.6 | 97 | 0.358 | 0.309 | 2.36 | 2.43 |
| Example 1 | | | | | | | | |
| Comparative | 29.6 | 60 | 46.2 | 95 | 0.112 | 0.283 | 0.93 | 2.36 |
| Example 2 | | | | | | | | |
| Comparative | 39.8 | 80 | 47.1 | 96 | 0.231 | 0.296 | 2.57 | 2.12 |
| Example 3 | | | | | | | | |
| Comparative | 46.1 | 95 | 46.1 | 92 | 0.383 | 0.301 | 2.03 | 2.62 |
| Example 4 | | | | | | | | |
| Comparative | 28.8 | 58 | 48.2 | 97 | 0.134 | 0.262 | 0.73 | 2.23 |
| Example 5 | | | | | | | | |
| Comparative | 38.4 | 79 | 45.9 | 95 | 0.208 | 0.235 | 2.32 | 2.04 |
| Example 6 | | | | | | | | |
| Embodiment | 37.8 | 76 | 46.5 | 95 | 0.271 | 0.289 | 1.87 | 2.22 |
| 1 | | | | | | | | |
| Embodiment | 36.6 | 73 | 46.7 | 94 | 0.256 | 0.232 | 1.53 | 2.57 |
| 2 | | | | | | | | |

The welding resistance and the chipping resistance of the cutting tool manufactured in this manner were evaluated under the following conditions.

(1) Welding resistance+chipping resistance evaluation
Workpiece material: STS304 hexagonal material
Model number: CNMG120408-VP3 (Comparative Examples 1 to 3, Embodiment 1)
Cutting speed: 120 m/min
Transfer per revolution: 0.15 mm/rev
Cutting depth: 0.8 mm

### (2) Welding Resistance Evaluation

Workpiece material: SKD11
Model number: ADKT170608PESR-MM (Comparative Examples 4 to 6, Embodiment 2)
Cutting speed: 120 m/min
Cutting transfer: 0.2 mm/tooth
Cutting depth: 5 mm

The processing results evaluated under the two conditions as described above are shown in Table 2 below.

TABLE 2

| | STS304 6 hexagonal material | | | |
|---|---|---|---|---|
| | machining results | | SCM440 machining results | |
| | Machining | Wear | Machining | Wear |
| Classification | depth (mm) | type | depth (mm) | type |
| Comparative | 9600 | Boundary chipping | — | — |
| Example 1 | | | | |
| Comparative | 8000 | Thin film peeling, | — | — |
| Example 2 | | chipping | | |
| Comparative | 12000 | Boundary chipping | — | — |
| Example 3 | | | | |
| Comparative | 14400 | Boundary chipping, | — | — |
| Example 4 | | normal wear | | |
| Comparative | — | — | 9000 | Fusion, excessive wear |
| Example 5 | | | | |
| Comparative | — | — | 6900 | Thin film peeling |
| Example 6 | | | | |
| Embodiment 1 | — | — | 10800 | Fusion, excessive wear |
| Embodiment 2 | — | — | 13500 | Normal wear |

As seen in Table 2 above, the cutting tool according to Embodiment was overall superior to the cutting tool according to Comparative Examples. Even if the same hard coating is applied, there is a significant difference in cutting performance depending on the surface treatment of the hard base material. In Comparative Examples 2 and 5, the results were shown, in which the roughness of the cutting tool is the best, but the lifespan is reduced due to the decrease in adhesion between the hard base material and the hard film. In Comparative Examples 3 and 6, since the roughness of the surface of the cutting tool is improved, the lifespan was improved, but there were limitations.

On the other hand, in Embodiments 1 and 2, the peeling and chipping of the hard film were suppressed, and the machining was performed most stably in the form of the normal wear. Through this, it was confirmed that the welding resistance and the chipping resistance were improved through the surface treatment of the hard base material before the film formation.

1. A hard film-coated cutting tool comprising:
a hard base material and
a hard film formed on the hard base material,
wherein, if assumed that a colorimetric diffusion reflectance value is L_{SCER}, and a total reflectance value is L_{SCIR} on a rake surface of the had film, a relationship of 0.65≤L_{SCER}/L_{SCIR}≤0.85 is satisfied, and when surface roughness is measured on the rake surface of the hard film within a range of 100 μm from an edge, an arithmetic average height S_{aR} is within a range of 0.2 μm≤S_{aR}≤0.5 μm, and if assumed that the colorimetric diffusion reflectance value is L_{SCEF}, and the total reflectance value is L_{SCIF} on a flank surface of the hard film, a relationship of L_{SCEF}/L_{SCIF}≥0.9 is satisfied, and when surface roughness is measured on the flank surface of the hard film within a range of 100 μm from the edge, an arithmetic average height S_{aF} is within a range of 0.15 μm≤S_{aF}≤0.4 μm.

2. The hard film-coated cutting tool of claim 1, wherein maximum height roughness R_{yR} of the hard base material within a range of 300 μm from the edge on the rake surface of the hard base material in a cross-section of the cutting tool is 1 μm≤R_{yR}≤2 μm, and
maximum height roughness R_{yF} of the hard base material within a range of 300 μm from the edge on the flank surface of the hard base material in the cross-section of the cutting tool is 2 μm≤R_{yF}≤5 μm.

3. The hard film-coated cutting tool of claim 1, wherein the hard film has a composition that satisfies Formula 1 below and comprises one or more films, each of which has a thickness in a range of 0.1 μm to 10.
[Formula 1]Al_{(1-a-b-c)}TiₐCr_{b}Me_{c}N (where Me is any one or more of B, Si, Zr, V, Mn, Nb, Mo, Ta, W, 0≤a≤0.6, 0≤b≤0.5, 0≤c≤0.15, and has to comprise at least one of Ti and Cr)

4. The hard film-coated cutting tool of claim 1, wherein the number of droplets, each of which has a diameter of 3 μm or more within 100 μm from the edge on the rake surface of the hard film, is 5% or less of the total number of droplets.
